(19) United States
(12) Patent Application Publication
(10) Pub. No.: US 2025/0212619 A1
(43) Pub. Date: Jun. 26, 2025

(54) DISPLAY APPARATUS

(71) Applicant: LG Display Co., Ltd., Seoul (KR)

(72) Inventors: Dae-Hee KIM, Paju-si (KR); Moon-Soo KIM, Paju-si (KR); Young-Kyun MOON, Paju-si (KR)

(73) Assignee: LG Display Co., Ltd., Seoul (KR)

(21) Appl. No.: 18/977,254

(22) Filed: Dec. 11, 2024

(30) Foreign Application Priority Data
Dec. 26, 2023 (KR) 10-2023-0191300

(51) Int. Cl. H10K 59/122; H10K 59/80

(52) U.S. Cl. CPC H10K 59/122; H10K 59/80522; H10K 59/873

(57) ABSTRACT

A display apparatus according to present disclosure includes a substrate including a plurality of first to third sub-pixels; a bank layer over the substrate to partition the plurality of sub-pixels; a transistor in each of the first to third sub-pixels; a light emitting device in each of the first to third sub-pixels, the light emitting device including a first electrode, a light emitting layer, and a second electrode; an auxiliary electrode over the bank layer; a first pattern and a second pattern having an overhang structure over the bank layer; and a plurality of first encapsulation layer formed in each of the plurality of first to third sub-pixels, the first encapsulation layer being partition by the second pattern, wherein the second electrode is electrically connected to the auxiliary electrode over the bank layer.

### CROSS-REFERENCE TO RELATED DISCLOSURE

The invention claims the priority of Korea Patent Disclosure No. 10-2023-0191300, filed on Dec. 26, 2023, which is hereby incorporated by reference.

### BACKGROUND

### Technical Field

The present disclosure relates to a display apparatus in which deterioration of elements during manufacture is prevented.

### Discussion of the Related Art

As information technology develops, various types of small and thin display apparatuses such as a Liquid Crystal Display Device, an Organic Light Emitting Display Device, a Plasma Display Device, a Micro LED Display Device, etc. are proposed. These display apparatuses are applied to various electronic devices such as smart phones and tablet PCs.

Inside the display apparatus, a display element including an organic light emitting layer, for example, and various electrodes are formed. The display apparatus includes a plurality of sub-pixels for displaying images of different colors, and a display device such as a light emitting device is disposed in each sub-pixel.

The display device is formed for each sub-pixel. That is, a first display device is formed in the first sub-pixel for displaying a first color, then a second display device is formed in the second sub-pixel for displaying a second color, and then the third display device is formed in the third sub-pixel for displaying a third color.

Accordingly, when forming the display device of a specific sub-pixel during the manufacturing process of the display apparatus, there is a problem that the display device disposed in the sub-pixel of the different color is damaged by chemicals such as an etchant or developer used in the manufacturing process of the corresponding sub-pixel.

### SUMMARY

Accordingly, embodiments of the present disclosure are directed to a display apparatus that substantially obviates one or more of the problems due to limitations and disadvantages of the related art.

An aspect of the present disclosure is to provide a display apparatus that can prevent damage of light emitting device sub-pixels during processing or manufacture of other sub-pixels by forming a separate first encapsulation layer in each sub-pixel.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display apparatus comprises a substrate including first to third sub-pixels; a bank layer on the substrate to partition the sub-pixels; a transistor in each of the first to third sub-pixels; a light emitting device in each of the first to third sub-pixels, at least one of the light emitting devices including a first electrode, a light emitting layer, and a second electrode; an auxiliary electrode on the bank layer; a first pattern and a second pattern having an overhang structure on the bank layer; and a plurality of first encapsulation layers, each first encapsulation layer formed on a respective sub-pixels of the first to third sub-pixels, the first encapsulations layer being partitioned by the second pattern, wherein the second electrode is electrically connected to the auxiliary electrode on the bank layer.

The first pattern and the second pattern may be disposed on the auxiliary electrode. The first pattern may be formed of an inorganic material and the second pattern may be formed of an amorphous semiconductor. The second electrode may extend to a side surface of the first pattern and may be connected to the side surface of the auxiliary electrode.

A protective layer may be disposed between the auxiliary electrode and the first pattern. The protective layer may be more readily oxidized than the auxiliary electrode and a width of the protective layer may be equal to the width of the auxiliary electrode.

The bank layer may include a first bank layer and a second bank layer on the first bank layer, and the second bank layer may include at least one bank opening. The bank opening may be formed at both sides of the first pattern and/or two sides of the second bank layer. The auxiliary electrode may be formed inside of the bank opening and the second electrode may be formed on the auxiliary electrode within the bank opening.

A low potential voltage line may be disposed on the bank layer. The first pattern may be disposed on the bank layer and a first pattern opening may be formed in the first pattern so that the low potential voltage line is exposed through the first pattern opening. The second pattern may be formed in the first pattern opening.

The auxiliary electrode may be formed on side and upper surfaces of the first pattern opening and inside the first pattern opening so that the auxiliary electrode is connected electrically to the low potential voltage line in the first pattern opening. The second electrode may be connected to the auxiliary electrode on the side surface of the first pattern.

A second encapsulation layer may be formed on the entire area of the substrate and on the plurality of first encapsulation layers. The display apparatus may comprise a third encapsulation layer on the second encapsulation layer.

The light emitting layer may include an organic light emitting layer, an inorganic light emitting layer, a nano-sized material layer, a quantum dot layer, a micro LED light emitting layer, or a mini LED light emitting layer.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a schematic block diagram of an organic light emitting display apparatus according to the present disclosure.

FIG. 2 is a schematic block diagram of a sub-pixel of the organic light emitting display apparatus according to the present disclosure.

FIG. 3 is a circuit diagram conceptually showing the sub-pixel of the organic light emitting display apparatus according to the present disclosure.

FIG. 4 is a cross-sectional view of a display apparatus according to a first embodiment of the present disclosure.

FIGS. 5A to 5G are views showing a method of manufacturing the display apparatus according to the first embodiment of the present disclosure.

FIG. 6 is a cross-sectional view of the display apparatus according to a second embodiment of the present disclosure.

FIG. 7 is the cross-sectional view of the display apparatus according to a third embodiment of the present disclosure.

FIG. 8 is the cross-sectional view of the display apparatus according to a fourth embodiment of the present disclosure.

### DETAILED DESCRIPTION

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and the present disclosure is defined only by the scope of the appended claims.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is used, one or more other parts may be located between the two parts.

In describing a temporal relationship, for example, when a temporal predecessor relationship is described as being “after,” “subsequent,” “next to,” “prior to,” or the like, unless “immediately” or “directly” is used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

In describing the components of the disclosure, terms such as first, second, A, B, (a), (b), etc. may be used. These terms are only for distinguishing the elements from other elements, and the essence, order, or number of the elements are not limited by the terms. When it is described that a component is “coupled” or “connected” to another component, the component may be directly coupled or connected to the other component, but indirectly without specifically stated. It should be understood that other components may be “interposed” between each component that is connected or can be connected.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the disclosure may include the display apparatus itself such as the LCM, the OLED module, etc., and the application product including the LCM, the OLED module, or the like, or the set apparatus, which is the apparatus for end users.

Hereinafter, the disclosure will be described in detail with reference to the accompanying drawings.

This disclosure can be applied to various display apparatuses. For example, this disclosure can be applied to apparatuses such as an organic light emitting display apparatus, a liquid crystal display apparatus, an electrophoretic display apparatus, a quantum dot display apparatus, a micro LED (Light Emitting Device) display apparatus, and a mini LED display apparatus. However, in the following description, an organic light emitting display apparatus will be described as an example for convenience of explanation.

Hereinafter, the present disclosure will be described in detail with reference to the drawings.

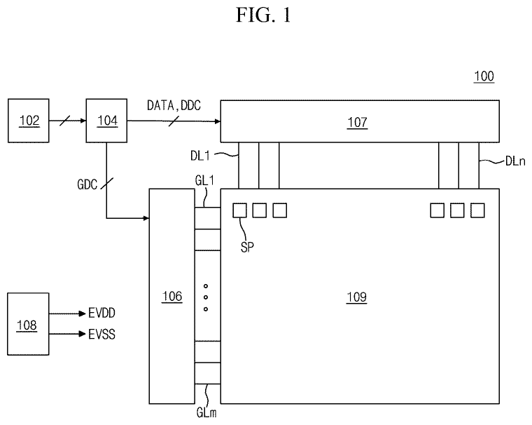

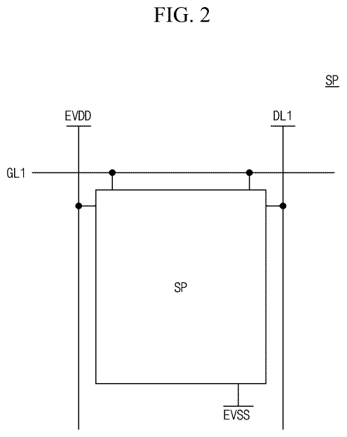

FIG. 1 is the schematic block diagram and FIG. 2 is the schematic block diagram of the sub-pixel of the organic light emitting display apparatus according to this disclosure.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GL1 to GLm. In this case, the gate driving unit 106 may be formed in the form of an integrated circuit (IC), but is not limited thereto. The gate driver 106 includes various gate driving circuits, and the gate driving circuits may be directly formed on the substrate 110. In this case, the gate driver 106 may be a gate-in-panel (GIP).

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DL1 to DLn. In this case, the data driving unit 107 may be mounted on the upper surface of the display panel 109 in the form of an integrated circuit (IC), but is not limited thereto.

The power supplying unit 108 outputs a high potential voltage VDD and a low potential voltage VSS etc. to supply these to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

The display panel 109 displays the image based on the data voltage from the data driving unit 108, the scan signal from the gage driving unit 106, and the power from the power supplying unit 108.

The display panel PAN includes a plurality of sub-pixels SP to display the image. The sub-pixel SP can include a Red sub-pixel, a Green sub-pixel, and a Blue sub-pixel. Further, the sub-pixel SP can include a White sub-pixel, a Red sub-pixel, a Green sub-pixel, and a Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to the gate line GL1, the data line DL1, the first power line EVDD, and the second power line EVSS. The sub-pixel SP may include a plurality of thin film transistors and a storage capacitor depending on the configuration of the pixel circuit. For example, the sub-pixel SP may include two transistors and one capacitor (called 2T1C), but is not limited thereto. The sub-pixel SP may be composed of 3T1C, 4T1C, 5T1C, 6T1C, 7T1C, 3T2C, 4T2C, 5T2C, 6T2C, 7T2, 8T2C, etc.

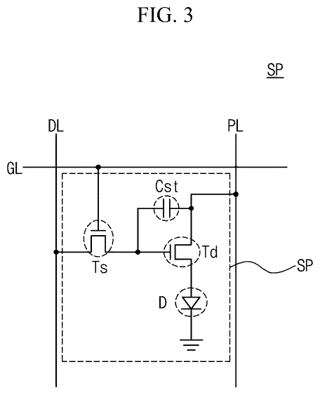

FIG. 3 is a circuit diagram illustrating the sub-pixel SP of the organic light emitting display apparatus 100 according to the present disclosure.

As shown in FIG. 3, the organic light emitting display apparatus 100 according to the present disclosure includes a gate line GL, data line DL, and power line PL crossing each other for defining the sub-pixel SP. A switching thin film transistor Ts, a driving thin film transistor DT, a storage capacitor Cst, and a light emitting device D are disposed in the sub-pixel SP.

The switching thin film transistor Ts is connected to the gate line GL and the data line DL, and the driving thin film transistor Td and the storage capacitor Cst are connected between the switching thin film transistor Ts and the power line PL. The light emitting device D is connected to the driving thin film transistor Td.

In the organic light emitting display apparatus having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode. As a result, the current proportional to the data signal is supplied to the light emitting device D from the power line PL through the driving thin film transistor Td and then the light emitting device D emits light with a luminance proportional to the current flowing through the driving thin film transistor Td.

At this time, the storage capacitor Cst is charged with the voltage proportional to the data signal to keep the voltage of the gate electrode of the driving thin film transistor Td constant for one frame.

In the figure, only two thin film transistors Td and Ts and one capacitor Cst are provided, but the present disclosure is not limited thereto. Three or more thin film transistors and two or more capacitors may be provided in the present disclosure.

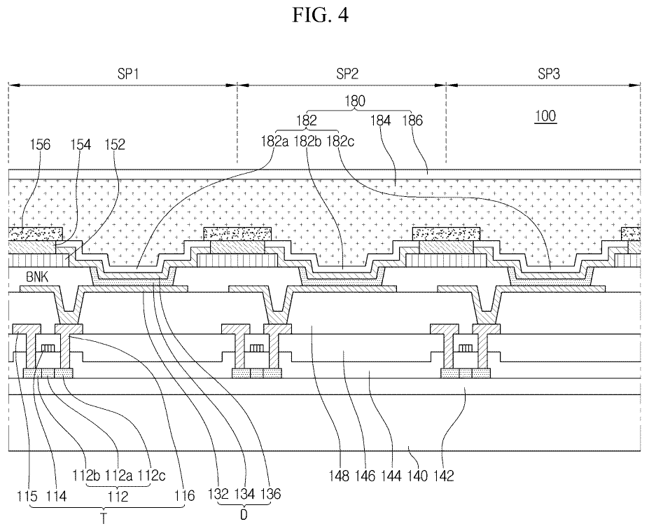

FIG. 4 is a cross-sectional view showing the structure of the sub-pixels of the display apparatus 100 according to the first embodiment of the present disclosure. Although a plurality of groups of sub-pixels are actually arranged in the display apparatus 100, only three adjacent sub-pixels SP1, SP2, and SP3 are shown in the drawing for convenience of explanation.

In this example, the sub-pixels SP1, SP2, and SP3 may include a red (R) sub-pixel, a green (G) sub-pixel, and a blue (B) sub-pixel, respectively. Further, the display apparatus 100 may further include a white (W) sub-pixel.

As shown in FIG. 4, a buffer layer 142 is formed on a substrate 140. The substrate 140 may be made of a hard material such as glass or a plastic material, but is not limited thereto. For example, the plastic material may be polyimide, polymethylmethacrylate, polyethylene terephthalate, polyethersulfone, or polycarbonate.

When the substrate 140 is made of polyimide, the substrate 140 may be made of a plurality of polyimide layers, and an inorganic layer may be further disposed between the polyimide layers, but is not limited thereto.

The buffer layer 142 may be formed on the entire area of the substrate 140 to enhance adhesion between the substrate 140 and the layers thereon. Further, the buffer layer 142 may block various types of defects, such as alkali components flowing out from the substrate 140. In addition, the buffer layer 142 may slow diffusion of moisture or oxygen penetrating into the substrate 140.

The buffer layer 142 may be a single layer made of silicon oxide (SiOx) or silicon nitride (SiNx), or multi-layers thereof. When the buffer layer 142 is made of multiple layers, SiOx and SiNx may be alternately formed. The buffer layer 142 may be omitted based on the type and material of the substrate 140, the structure and type of the thin film transistor, and the like.

A thin film transistor is formed on the buffer layer in each sub-pixel SP1, SP2, and SP3. For convenience of description, only the driving thin film transistor among various thin film transistors that may be disposed in the display area AA is illustrated, but other thin film transistors such as switching thin film transistors may also be included. In the figure, the thin film transistor of a top gate structure is shown, but the thin film transistor is not limited to this structure and may be formed in other structures such as the thin film transistor of a bottom gate structure.

The thin film transistor includes a semiconductor pattern 112 disposed on the buffer layer 142, a gate insulating layer 144 covering the semiconductor pattern 112, a gate electrode 113 on the gate insulating layer 144, an interlayer insulating layer 146 covering the gate electrode 113, and a source electrode 114 and a drain electrode 115 on the interlayer insulating layer 146.

The semiconductor pattern 112 may be made of a polycrystalline semiconductor. For example, the polycrystalline semiconductor may be made of low temperature poly silicon (LTPS) having high mobility, but is not limited thereto.

The semiconductor pattern 112 may be made of an oxide semiconductor. For example, semiconductor pattern 112 may be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers at the both sides of the channel region 112a.

The gate insulating layer 144 may be formed in the entire area of the substrate 140 or formed only in a part area of the substrate 140, for example only in the area below the gate electrode 113. The gate insulating layer 144 may be composed of a single layer or multiple layers made of an inorganic material such as SiOx or SiNx, but is not limited thereto.

The gate electrode 114 is made of a metal. For example, the gate electrode 114 may be formed of a single layer or multi layers made of one or more of molybdenum (Mo), aluminum (Al), chromium (Cr), gold (Au), titanium (Ti), nickel (Ni), neodymium (Nd), and copper (Cu), but is not limited thereto.

The interlayer insulating layer 146 may be made of an organic material such as photo-acryl, or the interlayer insulating layer 146 may be formed of a single layer or multiple layers made of an inorganic material such as SiOx or SiNx, but is not limited thereto. Further, the interlayer insulating layer 146 may be formed of multi layers of an organic material layer and an inorganic material layer, but is not limited thereto.

The source electrode 115 and the drain electrode 116 are formed of a single layer or multi layers made of one or more of molybdenum (Mo), aluminum (Al), chromium (Cr), gold (Au), titanium (Ti), nickel (Ni), neodymium (Nd), and copper (Cu), but is not limited thereto. The source electrode 115 and the drain electrode 116 may be respectively contacted to the source region 112b and the drain region 112c of the semiconductor through contact holes formed in the gate insulating layer 144 and the interlayer insulating layer 146.

Not shown in figure, a bottom shield metal layer may be disposed on the substrate 140 under the semiconductor pattern 112. The bottom shield metal layer minimizes a backchannel phenomenon caused by charges trapped in the substrate 140 to prevent afterimages or deterioration of transistor performance. The bottom shield metal layer may be composed of a single layer or multi layers made of titanium (Ti), molybdenum (Mo), or an alloy thereof, but is not limited thereto.

A planarization layer 148 is formed on the substrate where the thin film transistor is disposed. The planarization layer 148 may be formed of an organic material such as photo-acryl. But it is not limited thereto. The planarization layer 148 may include a plurality of layers including the inorganic layer and the organic layer.

A light emitting device D is disposed in each sub-pixel SP1, SP2, and SP3 on the planarization layer 148. The light emitting device D includes a first electrode 132, an organic layer 134, and a second electrode 136.

The first electrode 132 is disposed on the planarization layer 148 and electrically connected to the drain electrode 116 of the thin film transistor through the contact hole formed in the planarization layer 148. The first electrode 132 may be formed of at least one of silver (Ag), aluminum (Al), gold (Au), molybdenum (Mo), tungsten (W), chromium (Cr), or an alloy thereof. Further, the first electrode 132 may be formed of a transparent metal oxide material such as indium tin oxide (ITO) or indium zinc oxide (IZO).

When the display apparatus 100 is a top emission type display apparatus, the first electrode 132 may further include an opaque conductive material layer to function as a reflective electrode that reflects light. When the display apparatus 110 is a bottom emission type display apparatus, the first electrode 132 may be made of the transparent conductive material such as ITO or IZO.

A bank layer BNK is formed at the boundary between the sub-pixels SP1, SP2, and SP3 on the planarization layer 148. The bank layer BNK may be a barrier wall to define sub-pixels SP1, SP2, and SP3. The bank layer BNK divides each sub-pixel SP1, SP2, and SP3 to prevent light of a specific color output from adjacent pixels SP1, SP2, and SP3 from being mixed and output.

The bank layer BNK is formed to surround the sub-pixels SP1, SP2, and SP3, and an opening through which the first electrode 132 is exposed may be formed between the sub-pixels SP1, SP2, and SP3.

The bank layer BNK is made of at least one material of the inorganic insulating material such as SiNx or SiOx, the organic insulating material such as Benzocyclobutene, acrylic resin, epoxy resin, phenolic resin, polyamide resin, or a photosensitizer including black pigment, but is not limited thereto.

An auxiliary electrode 152 is disposed on the bank layer BNK. The auxiliary electrode 152 may be made of metal having good conductive properties. For example, the auxiliary electrode 152 may be formed of the single layer or the multiple layers made of at least one of molybdenum (Mo), aluminum (Al), chromium (Cr), gold (Au), titanium (Ti), nickel (Ni), neodymium (Nd), and copper (Cu), or an alloy thereof, but is not limited thereto.

Since the bank layer BNK is formed in a matrix shape over the entire area of the substrate 140, the auxiliary electrode 152 formed thereon is also formed in the matrix shape. Since the width of the auxiliary electrode 152 is smaller than that of the bank layer BNK, the upper surface of the bank layer BNK is exposed at both sides of the auxiliary electrode 152. However, it is not limited to this, and the width of the auxiliary electrode 152 and the width of the bank layer BNK may be the same.

The light emitting layer 134 is formed on the upper surface of the first electrode 132 exposed through the opening of the bank layer BNK.

For example, the light emitting layer 134 may be an organic light emitting layer. Further, the light emitting layer 134 may be an inorganic light emitting layer, such as a nano-sized material layer, quantum dot layer, micro LED light emitting layer, or mini LED light emitting layer, but is not limited thereto.

When the light emitting layer 134 is an organic light emitting layer, the light emitting layer 134 includes a blue organic light emitting layer and a yellow light emitting layer to output white light. The light emitting layer 134 may be formed in a multi-stack structure. For example, when the light emitting layer 134 is formed in a triple stack structure, the first to third stacks may be disposed with two charge generation layers therebetween. Each of the first to third stacks may include an organic light emitting layer, a hole injection layer, a hole transport layer, an electron transport layer, and an electron injection layer. For example, the organic light emitting layer of the first stack may emit red light, the organic light emitting layer of the second stack may emit blue light, and the organic light emitting layer of the third stack may emit green light.

A first pattern 154 and a second pattern 156 are formed on the auxiliary electrode 152. The first pattern 154 may also be known as a first pattern layer. The second pattern 156 may also be known as a second pattern layer.

At this time, since the bank layer BNK and the auxiliary electrode 152 are formed in the matrix shape over the entire area of the substrate 140, the first pattern 154 and the second pattern 156 are also formed in the matrix shape over the entire area of the substrate 140.

The width of the first pattern 154 is smaller than that of the auxiliary electrode 152, so that the auxiliary electrode 152 protrudes outward from both sides of the first pattern 154 and the upper surface of the auxiliary electrode 152 is exposed, but is not limited thereto. Further, the width of the first pattern 154 is smaller than that of the second pattern 156 so that the second pattern 156 overhangs the first pattern 154.

The first pattern 154 may be made of an inorganic material such as SiOx or SiNx, but is not limited thereto. The second pattern 156 may be made of amorphous silicon, but is not limited thereto.

The second electrode 136 is disposed on the organic layer 134. When the display apparatus 100 is a top emission type, the second electrode 136 may be made of a half-transparent conductive material that transmits light. For example, the second electrode 188 may be made of at least one or more of the alloys such as LiF/Al, CsF/Al, Mg:Ag, Ca/Ag, Ca:Ag, LiF/Mg:Ag, LiF/Ca/Ag, or LiF/Ca:Ag.

When the display apparatus 100 is a bottom emission type, the second electrode 136 may be a reflective electrode made of an opaque conductive material. For example, the second electrode 188 may be made of at least one or more of silver (Ag), aluminum (Al), gold (Au), molybdenum (Mo), tungsten (W), chromium (Cr), or alloys thereof.

The second electrode 136 is extended to the upper surface of the exposed bank layer BNK, the side surface and the exposed upper surface of the auxiliary electrode 152, and the side surface of the first pattern 154. That is, the second electrode 136 is electrically connected to a part of the side surface and the upper surface of the auxiliary electrode 152.

In the display apparatus 100 according to the present disclosure, the second electrode 136 is formed in each of the sub-pixels SP1, SP2, and SP3 so that each second electrode 136 of the sub-pixels SP1, SP2, and SP3 is separated from the second electrode 136 of the adjacent sub-pixel SP1, SP2, and SP3, but the second electrodes 136 of adjacent sub-pixels SP1, SP2, and SP3 are electrically connected to each other by the auxiliary electrode 152. That is, the second electrode 136 is electrically connected throughout the display apparatus 100 by the auxiliary electrode 152, and the signal applied from outside is supplied to the second electrode 136 in the entire area of the display apparatus 100.

Further, the auxiliary electrode 152 can prevent defects in the display apparatus 100 due to signal delay. When the display apparatus 100 is the top emission type, since the transparent conductive material forming the second electrode 136 has a relatively high resistance, the signals are delayed in the large area display apparatus 100. However, in the present disclosure, the auxiliary electrodes 152 having good conductivity are formed in the matrix form over the entire area of the display apparatus 100 and the second electrode 136 is electrically connected to the auxiliary electrode 152, so that the signal delay of the second electrode 136 in the display apparatus can be reduced or prevented.

The first pattern 154 and the second pattern 156 are formed with a overhang structure having a reverse step. As will be described later, the overhang structure of the first pattern 154 and the second pattern 156 is for patterning the light emitting layer 134 and the second electrode 136 for each sub-pixel. That is, in the present disclosure, by forming the first pattern 154 and the second pattern 156 with an overhang structure, the light emitting layer 134 and the second electrode 136 can be formed without a separate mask, so that the manufacturing process can be simplified and the manufacturing cost can be reduced.

An encapsulation layer 180 is formed over the light emitting device D. When the light emitting device D is exposed to impurities such as moisture or oxygen, a pixel shrinkage phenomenon in which the light emitting area is reduced or the defect such as a dark spot in the light emitting area may occur. Further, moisture or oxygen penetrating into the light emitting device D oxidizes the metal electrode. The encapsulation layer 180 blocks impurities such as oxygen and moisture from outside to prevent defects of the light emitting device D and various electrodes.

The encapsulation layer 180 may be formed of first encapsulation layers 182a, 182b, and 182c, a second encapsulation layer 184, and a third encapsulation layer 186, but is not limited thereto. The encapsulation layer 180 may be formed of two layers or four or more layers.

The first encapsulation layers 182a, 182b, and 182c are formed in the sub-pixels SP1, SP2, and SP3, respectively. That is, while the second encapsulation layer 184 and the third encapsulation layer 186 are integrally formed over the entire area of the substrate, the first encapsulation layers 182a, 182b, and 182c are formed only in the corresponding sub-pixels SP1, SP2, and SP3. Each of the first encapsulation layers 182a, 182b, and 182c is formed to cover the entire area of the second electrode 136 of the corresponding sub-pixel SP1, SP2, and SP3. In the drawing, the upper surface of the first encapsulation layer 182a, 182b, and 182c and the lower surface of the second pattern 156 are at the same level, but the disclosure is not limited thereto.

The first encapsulation layers 182a, 182b, and 183c and the third encapsulation layer 186 may be made of an inorganic material such as SiOx or SiNx, but are not limited thereto. The second encapsulation layer 184 may be made of an organic insulating material such as acrylic resin, epoxy resin, polyimide, polyethylene, or silicon oxycarbon (SiOC), but is not limited thereto. Further, the third encapsulation layer 186 may be made of thin metal (such as Face Seal Metal), but is not limited thereto.

As described above, in the display apparatus 100 according to the present disclosure, since the light emitting element D is formed for each sub-pixel SP1, SP2, and SP3, the light emitting layer 134 is disconnected between the adjacent sub-pixels SP1, SP2, and SP3. Accordingly, the current flow path is not generated between the adjacent sub-pixels SP1, SP2, and SP3, so that the lateral leakage current between the adjacent sub-pixels SP1, SP2, and SP3 can be reduced or prevented.

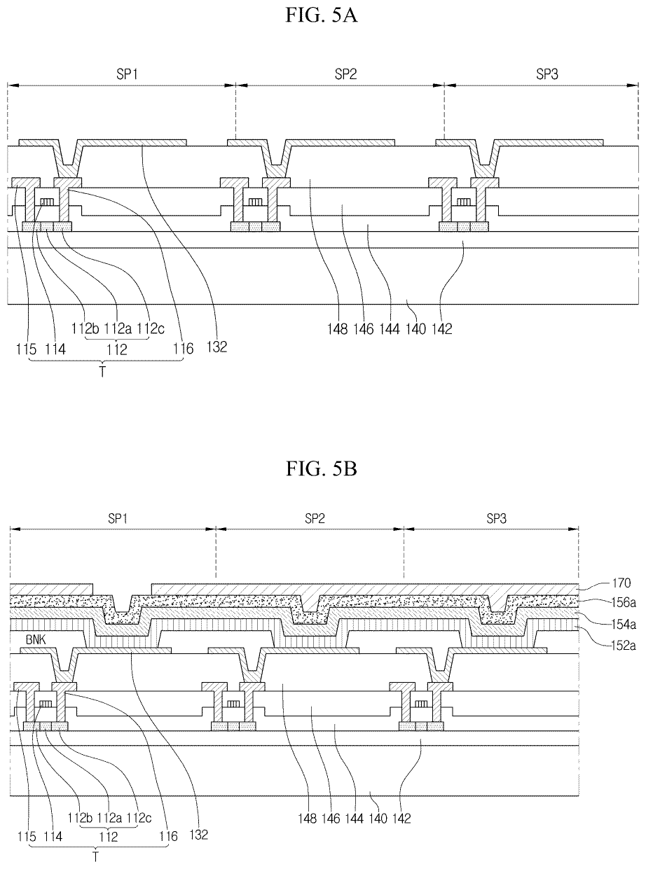

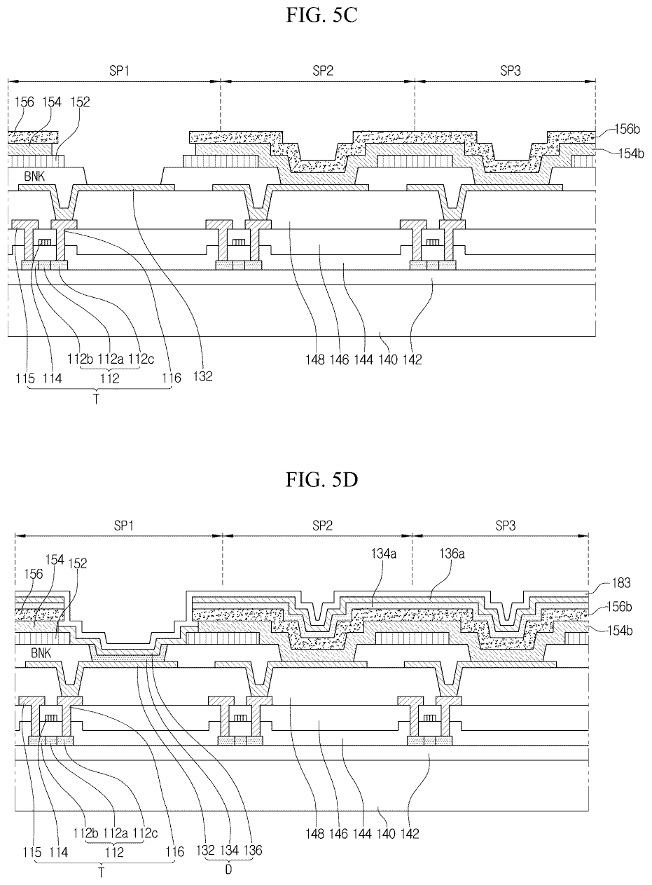

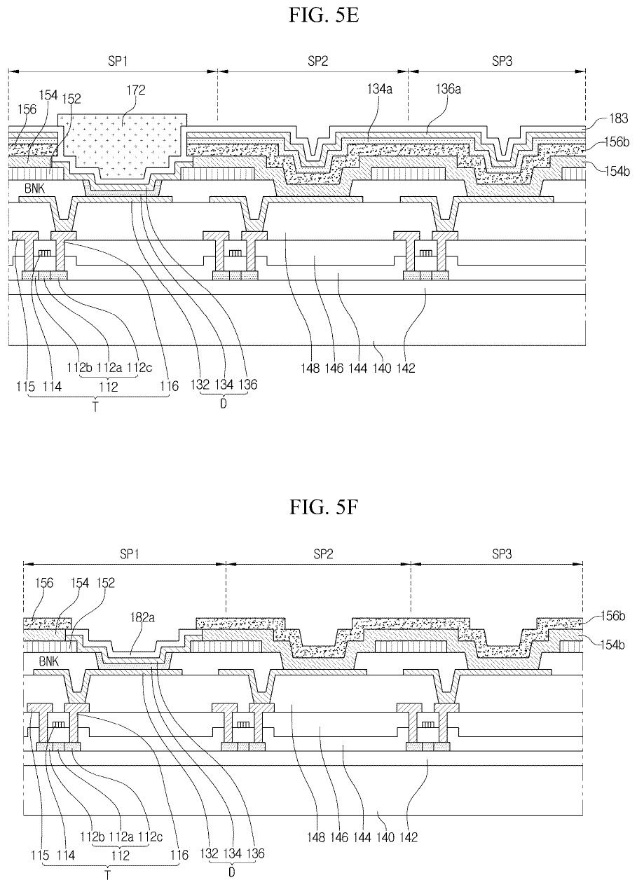

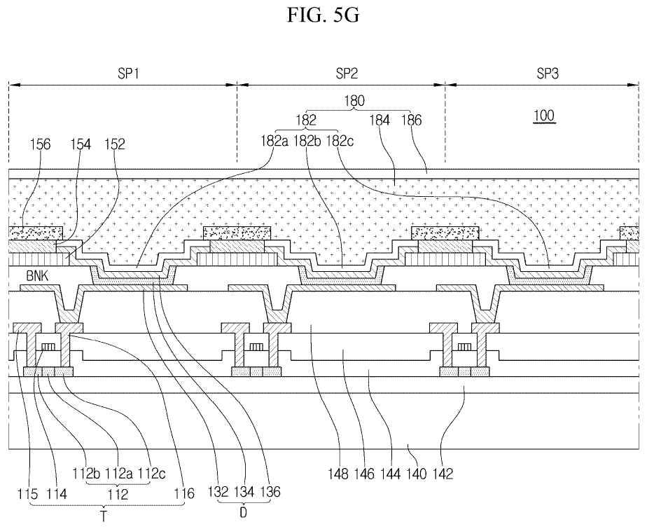

Further, in the present disclosure, the first encapsulation layers 182a, 182b, and 182c are not formed over the entire area of the substrate 140, but only in each respective sub-pixel SP1, SP2, and SP3. Therefore, during the photo process (see, for example, FIGS. 5A to 5G below) of a specific sub-pixel (e.g., the third sub-pixel SP3), the components such as the light emitting device D disposed in the different sub-pixels (e.g., the first and second sub-pixels SP1 and SP2) is not damaged by chemicals used in the photo process of the corresponding sub-pixel (e.g., the third sub-pixel SP3).

In addition, in the present disclosure, the contact area between the second electrode 136 and the auxiliary electrode 152 is maximized by contacting the second electrode 136 with the side and upper surfaces of the auxiliary electrode 152, so that defects caused by signal delay in the second electrode 136 can be reduced or prevented.

Hereinafter, a manufacturing method of the display apparatus 100 according to the first embodiment of the present disclosure will be described in detail.

FIGS. 5A to 5G are views showing the method of manufacturing the display apparatus 100 according to the first embodiment of the present disclosure.

First, as shown in FIG. 5A, the buffer layer 142 is formed over the entire substrate 140 including a plurality of sub-pixels SP1, SP2, SP3. The substrate 140 may be made of a hard material such as glass or a plastic material such as a plastic material including a polyimide, a polymethylmethacrylate, a polyethylene terephthalate, a polyethersulfone, or a polycarbonate. The buffer layer 142 may be formed of the single layer of SiNx or SiOx, or multiple layers thereof.

Thereafter, the poly-crystalline semiconductor material such as poly-silicon or the oxide semiconductor material such as IGZO (Indium-gallium-zinc-oxide), IZO (Indium-zinc-oxide), IGTO (Indium-gallium-tin-oxide), and IGO (Indium-gallium-oxide) is deposed and etched to form the semiconductor layer 112 in each of the first to third sub-pixels SP1, SP2, and SP3 on the buffer layer 142. Further, the impurities are doped into both sides of the semiconductor layer 112 to form the channel region 112a, the source region 112b, and the drain region 112c.

Subsequently, the gate insulating layer is formed 144 by depositing the inorganic material such as SiOx or SiNx, and then the metal such as molybdenum (Mo), aluminum (Al), chromium (Cr), gold (Au), titanium (Ti), nickel (Ni), Neodymium (Nd) and copper (Cu) are deposited by the sputtering method and etched by the wet etching method to form the gate electrode 114. Thereafter, organic material such as photosensitive acrylic material or inorganic material such as SiNx or SiOx is deposited on the gate electrode 114 to form the interlayer insulating layer 146, and then the interlayer insulating layer 146 over the source region 112b and the drain region 112c of the semiconductor layer 112 is dry-etched to form the contact holes therein.

Subsequently, metal such as Cr, Mo, Ta, Cu, Ti, Al, or an Al alloy is deposited by sputtering and etched to form the source electrode 115 and the drain electrode 116 which are respectively ohmic-contacted to the source region 112b and the drain region 112c of the semiconductor layer 112 through the contact holes in each of the first to third sub-pixels SP1, SP2, and SP3.

Thereafter, the planarization layer 148 is formed by depositing organic material such as photo-acryl on the source electrode 115 and the drain electrode 116, and then the planarization layer 148 on the drain electrode 116 is dry-etched to form the contact hole. Thereafter, the metal or the metal oxide is deposited on the planarization layer 148 by sputtering and etched by wet etching to form the first electrode 132 electrically connected to the drain electrode 116 through the contact hole in each of the sub-pixels SP1, SP2, and SP3.

Thereafter, as shown in FIG. 5B, at least one material of an inorganic insulating material such as SiNx or SiOx, organic material such as BCB (BenzoCycloButene), acrylic resin, epoxy resin, phenolic resin, polyamide resin, and polyimide resin, and photoresist including black pigment is deposited on an edge area of the planarization layer 148 and the first electrode 132 and dry-etched to form the bank layer BNK.

At this time, the bank layer BNK is formed in a matrix shape over the entire area of the substrate 140 and overlapped with the edge of the first electrode 132, so that the first electrode 132 is exposed through the opening between the bank layers BNK.

Subsequently, at least one metal such as molybdenum (Mo), aluminum (Al), chromium (Cr), gold (Au), titanium (Ti), nickel (Ni), neodymium (Nd), and copper (Cu), or an alloy thereof, is deposited to form a metal layer 152a and then an inorganic material and amorphous silicon are continuously deposited to form the first pattern 154a and the second pattern 156a.

Thereafter, a photoresist is deposited on the second pattern layer 156a and then the photoresist in the area corresponding to the first sub-pixel SP1 is removed using a mask to form a first photoresist pattern 170.

Subsequently, as shown in FIG. 5C, a metal layer 152a, first pattern layer 154a, and second pattern layer 156a are etched using the first photoresist pattern 170 as a mask to form the auxiliary electrode 152, a first pattern 154b, and a second pattern 156b in the sub-pixel SP1, and to expose the first electrode 132.

At this time, the metal layer 152a, the first pattern layer 154a, and the second pattern layer 156a are etched in multiple steps, so that the first pattern 154b and the second pattern 156b are formed with an overhang structure. That is, the second pattern layer 156a is etched by a dry etching process while blocked by the first photoresist pattern 170, and then the first pattern layer 154a is etched by a wet etching process. At this time, the first pattern layer 154a is isotropically etched by the etchant, and a part of the first pattern layer 154a below the second pattern 156b is also etched to form the first pattern 154b and the second pattern 156b with the undercut shape. The metal layer 152a is etched by the etchant using the first pattern 154 and the second pattern 156 as the mask to form the auxiliary electrode 152 having the same width as the first pattern 154.

Subsequently, as shown in FIG. 5D, an organic material is deposited over the entire area of the substrate 140 and then a metal such as silver (Ag), aluminum (Al), gold (Au), molybdenum (Mo), tungsten (W), and chromium (Cr) are deposited thereon. At this time, the first pattern layer 154a and the second pattern layer 154b of the first sub-pixel SP1 are etched, and thus the first electrode 132 below the first pattern layer 154a and the second pattern layer 154b is exposed. On the other hand, the second sub-pixel SP2 and the third sub-pixel SP3 are covered by the first pattern layer 154a and the second pattern layer 154b, and the first pattern 154 and the second pattern 156 are formed with a overhang structure, so that the light emitting layer 134 and the second electrode 136 are formed on the first electrode 132 of the first sub-pixel SP1.

At this time, since the second electrode 136 is formed by an evaporation process, despite the overhang structure of the first pattern 154 and the second pattern 156, the second electrode 136 is formed on the upper surface of the auxiliary electrode 152 and the side surfaces of the first pattern 154 to be connected electrically to the auxiliary electrode 152.

Further, the organic pattern 134a and the metal pattern 136a are formed on the second pattern layer 156a of the second sub-pixel SP1 and the third sub-pixel SP3.

Subsequently, the inorganic material such as SiOx or SiNx is deposited over the entire area of the substrate 140 to form inorganic layer 183.

Thereafter, as shown in 5E, the photoresist is deposited over the entire area of the substrate 140 to cover the inorganic layer 183 and then developed to form a second photoresist pattern 172 on the inorganic layer 183 of the first sub-pixel SP1.

Thereafter, as shown in FIG. 5F, the organic pattern 134a, the metal pattern 136a, and the inorganic layer 183 are etched in a state in which a part of the inorganic layer 183 is blocked by the second photoresist pattern 172 to form the first encapsulation layer 182a and the first sub-pixel SP1 and to expose the first pattern layer 154a and a second pattern layer 156a in the second sub-pixel SP2 and the third sub-pixel SP3.

Subsequently, the processes of FIGS. 5B to 5F are repeated for the second sub-pixel SP2 and the third sub-pixel SP3, and the first encapsulation layers 182b and 182c is respectively formed in the second sub-pixel SP2 and the third sub-pixel SP3.

Thereafter, organic material is deposited over the entire area of the substrate 140 on which the first encapsulation layers 182a, 182b, and 182c are formed to form the second encapsulation layer 184, and then inorganic material is deposited over the second encapsulation layer 184 to form the third encapsulation layer 186, thereby forming the encapsulation layer 180 for sealing the display apparatus 100.

As described above, in the manufacturing method of the display apparatus 100 according to the present disclosure, the first pattern 254 and the second pattern 256 are formed with an overhang structure to form the light emitting layer 134 and the second electrode 136 so that a separate photo process for patterning the light emitting layer 134 and the second electrode 136 is not required, and thus the manufacturing process can be simplified and manufacturing costs can be reduced.

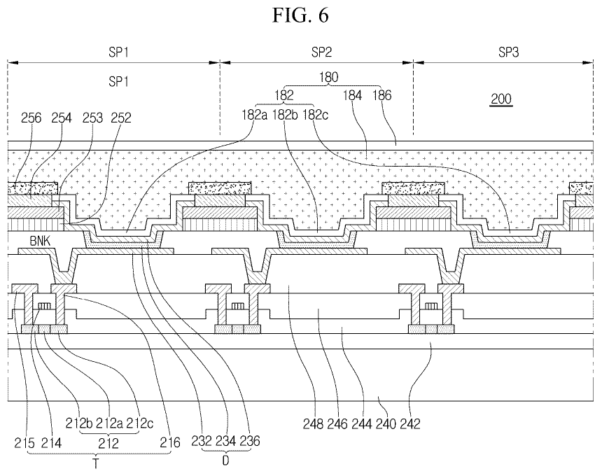

FIG. 6 is the view showing the display apparatus 200 according to a second embodiment of the present disclosure. At this time, the description of the same structure as the first embodiment of FIG. 4 will be omitted or simplified, and only different structures will be described in detail.

As shown in FIG. 6, the thin film transistor T and the light emitting device D are disposed in each of the sub-pixels SP1, SP2, and SP3 of the substrate 240.

The thin film transistor T includes the semiconductor layer 212 disposed on the buffer layer 242, the gate electrode 214 disposed on the gate insulating layer 244, the source electrode 215 and the drain electrode 216 disposed on the interlayer insulating layer 246.

The planarization layer 248 is formed on the thin film transistor T, and the bank layer BNK is formed in the matrix shape between the sub-pixels SP1, SP2, and SP3 on the planarization layer 248. The light emitting device D includes a first electrode 232, a light emitting layer 234, and a second electrode 236. The first electrode 232, the light emitting layer 234, and the second electrode 236 are respectively disposed in the sub-pixels SP1, SP2, and SP3 and are disconnected from adjacent sub-pixels.

The auxiliary electrode 252 is disposed on the upper surface of the bank layer BNK, and a protective layer 253 is disposed on the auxiliary electrode 252. The width of the auxiliary electrode 252 may be smaller than that of the bank layer BNK, and the width of the protective layer 253 may be the same as that of the auxiliary electrode 252, but is not limited thereto.

The protective layer 253 may be made of metal. For example, the protective layer 253 may be made of a metal having relatively stronger oxidization properties (i.e. is more readily oxidized) than the auxiliary electrode 252 disposed below, so that the protective layer 253 is oxidized instead of the auxiliary electrode 252 in an environment where the auxiliary electrode 252 may be oxidized, thereby preventing oxidization of the auxiliary electrode 252.

Further, from this point of view, even in the area where the auxiliary electrode 252 and the second electrode 236 are in contact, the protective layer 253 is oxidized instead of the auxiliary electrode 252 and the second electrode 236. As a result, oxidization of the auxiliary electrode 252 and the second electrode 236 can be prevented.

The first pattern 254 and the second pattern 256 are disposed on the protective layer 252. At this time, the width of the first pattern 254 is smaller than that of the second pattern 256, so that the first pattern 254 and the second pattern 256 are formed with an overhang structure. Due to this overhang structure, a separate mask process is not required when forming the light emitting layer 234 and the second electrode 236 of the organic light emitting device D.

The second electrode 236 is disposed on the light emitting layer 234 and extends to a part of the upper surface of the bank layer BNK, a side surface of the auxiliary electrode 252, and one side surface and a part of the upper surface of the first pattern 254, so that the second electrode 236 is electrically connected to the side surface of the auxiliary electrode 252. That is, since the second electrodes 236 of the entire area of the display apparatus 200 are electrically connected by the auxiliary electrode 252, the signal (voltage) is supplied to the second electrodes 236 of the entire area of the display apparatus 200 at once.

The separated first encapsulation layers 282a, 282b, and 282c are formed in each of the sub-pixels SP1, SP2, and SP3 which are partitioned by the second pattern 256, and then the second encapsulation layer 284 and the third encapsulation layer 286 are is formed over the entire area of the substrate 240 to form the encapsulation layer 280 for encapsulating the display apparatus 200.

As described above, in the display apparatus 200 of this embodiment, the protective layer 253 made of a metal having relatively stronger oxidization property than the auxiliary electrode 252 is formed on the auxiliary electrode 252 to be oxidized instead of the auxiliary electrode 252. Since layer 254 is oxidized, oxidization of the auxiliary electrode 252 can be prevented.

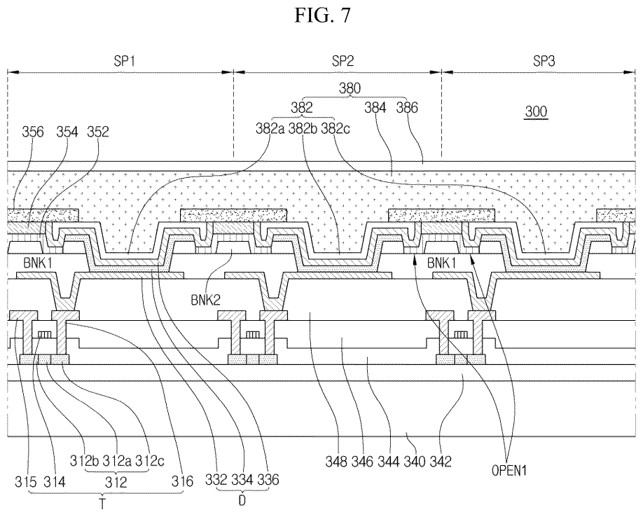

FIG. 7 is the view showing the display apparatus 300 according to a third embodiment of the present disclosure. At this time, the description of the same structure as the first embodiment of FIG. 4 will be omitted or simplified, and only different structures will be described in detail.

As shown in FIG. 6, the thin film transistor T and the light emitting device D are disposed in each of the sub-pixels SP1, SP2, and SP3 of the substrate 340.

The thin film transistor T includes the semiconductor layer 312 disposed on the buffer layer 342, the gate electrode 314 disposed on the gate insulating layer 344, the source electrode 315 and the drain electrode 316 disposed on the interlayer insulating layer 346.

The planarization layer 348 is formed on the thin film transistor T, and a bank layer BNK1, BNK 2 is formed in the matrix shape between the sub-pixels SP1, SP2, and SP3 on the planarization layer 348. The bank layer includes a first bank layer BNK1 and a second bank layer BNK2 thereon. In the drawing, the widths of the top of the first bank layer BNK1 and the bottom of the second bank layer BNK2 are the same, but the width of the bottom of the first bank layer BNK1 is larger than that of the second bank layer BNK2 so that the first bank layer BNK1 extends to the outside of both sides of the second bank layer BNK2. The first bank layer BNK1 may be formed of a hydrophilic material and the second bank layer BNK2 may be formed of a hydrophobic material, but are not limited thereto.

A bank opening OPEN1 is formed along the longitudinal direction in the second bank layer BNK2. In the drawing, two bank openings OPEN1 are formed, but is not limited thereto. Two or more bank openings OPEN1 may be formed, or only one bank opening OPEN1 may be formed.

The bank opening OPEN1 is formed only in the second bank layer BNK2, so that the lower first bank layer BNK1 can be exposed through the bank opening OPEN1. However, it is not limited to this. If only a part of the thickness of the second bank layer BNK2 is removed to form the bank opening OPEN1, the bottom of the bank opening OPEN1 may be the second bank layer BNK2. Further, if the entire thickness of the second bank layer BNK2 and a part of the first bank layer BNK1 are removed to form the bank opening OPEN1, the bottom of the bank opening OPEN1 may be the first bank layer BNK1.

The organic light emitting element D disposed in each of the sub-pixels SP1, SP2, and SP3 partitioned by the bank layer BNK1, BNK2 includes a first electrode 332, a light emitting layer 334, and a second electrode 336. The first electrode 332, the light emitting layer 334, and the second electrode 336 are respectively disposed in the sub-pixels SP1, SP2, and SP3 and are disconnected from adjacent sub-pixels.

The auxiliary electrode 352 is disposed on the upper surface of the second bank layer BNK2, and the first pattern 354 and the second pattern 356 having an overhang structure are disposed on the auxiliary electrode 352. The auxiliary electrode 352 is also formed inside the opening OPEN. In the drawing, the auxiliary electrode 352 is formed only in a partial area of the opening OPEN, but may be formed in the entire area of the opening OPEN.

At this time, bank openings OPEN1 may be formed on both sides of the first pattern 354, but are not limited thereto.

The first electrode 332 of the organic light emitting device D is formed on the planarization layer 348 of each of the sub-pixels SP1, SP2, and SP3, and the light emitting layer 334 is formed on the first electrode 332. The second electrode 336 is formed on the light emitting layer 334 and extends on the second bank layer BNK2. At this time, the second electrode 336 is extended to the side surface of the first pattern 355 through the side surfaces of the first and second bank layers BNK1 and BNK2, the upper surface of the second bank BNK2, and the inside of the bank opening OPEN1 formed in the second bank layer BNK2.

Compared to the display apparatus 100 of the first embodiment shown in FIG. 4, the second electrode 336 of this embodiment is also formed inside the opening OPEN, so that compared to the first embodiment, the length of the second electrode 336 is increased.

In general, since the light emitting layer 334 made of the organic material is deteriorated by penetrated moisture or oxygen, the moisture or the oxygen penetrating into the organic material must be blocked to prevent defects in the light emitting device D. The moisture or the oxygen penetrates into the light emitting layer 334 through the interface between the second electrode 336 and the bank layer BNK1, BNK2.

In this embodiment, by forming a bank opening OPEN1 to increase the length of the interface between the second electrode 336 and the second bank layer BNK2, the penetration distance of the moisture or the oxygen to the light emitting layer 334 is increased so that penetration of moisture or oxygen to the light emitting layer 334 can be minimized.

Further, in this embodiment, the auxiliary electrode 352 is formed in part or the entire area of the bank opening OPEN1 and the second electrode 336 is extended inside the bank opening OPEN1, so that the contact area between the second electrode 336 and the auxiliary electrode 352 is increased significantly. Thus, it is possible to minimize signal delay in the second electrode 336 throughout the display apparatus 300.

The first encapsulation layers 382a, 382b, and 382c are separately formed in each of the sub-pixels SP1, SP2, and SP3 partitioned by the second pattern 356, and the second encapsulation layer 384 and the third encapsulation layer 386 are formed over the entire area of the substrate 340 to form the encapsulation layer 380 for encapsulating the display apparatus 300.

As described above, in the display apparatus 300 of this embodiment, the bank layer BNK1, BNK2 is formed of two bank layers (that is, BNK1 and BNK2), the bank opening OPEN1 is formed in the upper second bank layer BNK2, and the second electrode 336 is formed within the bank opening OPEN1, so that the electrical contact area between the second electrode 336 and the auxiliary electrode 352 is increased, thereby blocking easily the penetration of the moisture or the oxygen from outside.

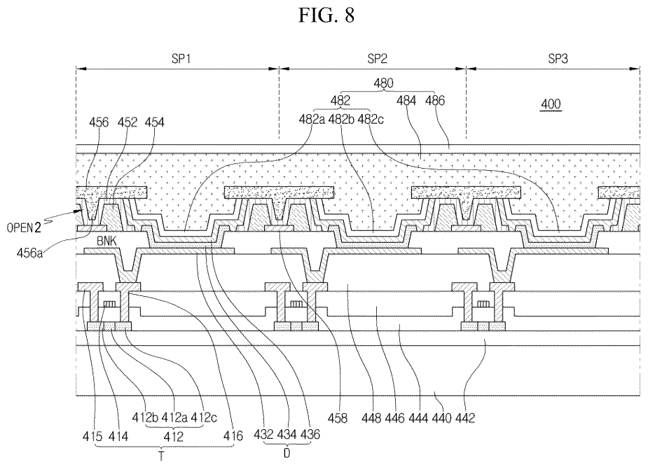

FIG. 8 is a view showing the display apparatus 400 according to a third embodiment of the present disclosure. At this time, the description of the same structure as the first embodiment of FIG. 4 will be omitted or simplified, and only different structures will be described in detail.

As shown in FIG. 6, the thin film transistor T and the light emitting device D are disposed in each of the sub-pixels SP1, SP2, and SP3 of the substrate 440.

The thin film transistor T includes the semiconductor layer 412 disposed on the buffer layer 442, the gate electrode 414 disposed on the gate insulating layer 444, the source electrode 415 and the drain electrode 416 disposed on the interlayer insulating layer 446.

The planarization layer 448 is formed on the thin film transistor T, and a bank layer BNK is formed in a matrix shape between the sub-pixels SP1, SP2, and SP3 on the planarization layer 448.

A low potential voltage line 458 is disposed on the bank layer BNK. The low potential voltage line 458 is electrically connected to an external power supply to supply an external low potential voltage to the light emitting device D. The low potential voltage line 458 may be disposed on all area of the bank layers BNK formed on the substrate 440, or may be disposed on only a part of the bank layers BNK.

The first pattern 454 and the second pattern 456 having an overhang structure are formed on the low potential voltage line 458. At this time, the width of the first pattern 454 is larger than that of the low potential voltage line 458, so that the low potential voltage line 458 is formed only at the lower portion of the first pattern 454 is and not extended to the outside of the first pattern 454.

The first pattern opening OPEN2 is formed in the first pattern 454 so that the lower low potential voltage line 458 is exposed through the first pattern opening OPEN2, and the second pattern 456 is formed inside the first pattern opening OPEN2. That is, a concave portion OPEN2 is formed in the first pattern 454 and a protrusion portion 456a is formed in the second pattern 456, so that the protrusion portion 456a of the second pattern 456 and the concave portion OPEN2 of the first pattern 454 are joined tightly.

The auxiliary electrode 454 is formed on a side surface of the first pattern 454, on an upper surface of the first pattern 454 (i.e., between the first pattern 454 and the second pattern 456), and inside of the first pattern opening OPEN2 over the bank layer BNK. At this time, the auxiliary electrode 454 is electrically connected to the lower low potential voltage line 458 inside the first pattern opening OPEN2.

The organic light emitting element D disposed in each of the sub-pixels SP1, SP2, and SP3 partitioned by the bank layer BNK includes a first electrode 432, a light emitting layer 434, and a second electrode 436. The first electrode 432, the light emitting layer 434, and the second electrode 436 are respectively disposed in the sub-pixels SP1, SP2, and SP3 and are disconnected from adjacent sub-pixels.

The second electrode 436 is disposed on the light emitting layer 434 and is extended to an upper surface of the auxiliary electrode 452 disposed at the side of the first pattern 454 and is electrically connected to the auxiliary electrode 452.

Compared to the display apparatus 100 of the first embodiment shown in FIG. 4, the auxiliary electrode 152 is disposed below the first pattern 154 and the second electrode 136 is contacted with the side surface of the auxiliary electrode 152 in the display apparatus 100 of the first embodiment, whereas the auxiliary electrode 452 is formed on a part of the upper surface of the bank layer BNK and the side and top surfaces of the first pattern 454 in the display apparatus 400 of this embodiment. Therefore, in this embodiment, the electrical contact area between the second electrode 436 and the auxiliary electrode 452 is increased so that the signal delay signal delay in the second electrode 436 throughout the display apparatus 400 can be prevented.

Further, in the display apparatus 400 of this embodiment, since the low potential voltage line 458 is formed on the bank layer BNK of the display area, not the outer area of the display apparatus 400 to supply the low potential voltage to the second electrode through the auxiliary electrode 452, a uniform low potential voltage can be applied throughout the entire area of the display apparatus 400.

The first encapsulation layers 482a, 482b, and 482c are separately formed in each of the sub-pixels SP1, SP2, and SP3 partitioned by the second pattern 456, and the second encapsulation layer 484 and the third encapsulation layer 486 are formed over the entire area of the substrate 440 to form the encapsulation layer 480 for encapsulating the display apparatus 400.

It will be apparent to those skilled in the art that various modifications and variations can be made in the display apparatus of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display apparatus, comprising:
a substrate including first to third sub-pixels;
a bank layer on the substrate to partition the sub-pixels;
a transistor in each of the first to third sub-pixels;
a light emitting device in each of the first to third sub-pixels, at least one of the light emitting devices including a first electrode, a light emitting layer, and a second electrode;
an auxiliary electrode on the bank layer;
a first pattern and a second pattern having an overhang structure on the bank layer; and
a plurality of first encapsulation layers, each first encapsulation layer formed on a respective sub-pixel of the first to third sub-pixels, the first encapsulation layers being partitioned by the second pattern,
wherein the second electrode is electrically connected to the auxiliary electrode on the bank layer.

2. The display apparatus of claim 1, wherein the first pattern and the second pattern are disposed on the auxiliary electrode.

3. The display apparatus of claim 2, wherein the first pattern is formed of an inorganic material and the second pattern is formed of an amorphous semiconductor.

4. The display apparatus of claim 2, wherein the second electrode extends to a side surface of the first pattern and is connected to the side surface of the auxiliary electrode.

5. The display apparatus of claim 2, further comprising a protective layer between the auxiliary electrode and the first pattern.

6. The display apparatus of claim 5, wherein the protective layer is more readily oxidized than the auxiliary electrode.

7. The display apparatus of claim 5, wherein a width of the protective layer is equal to the width of the auxiliary electrode.

8. The display apparatus of claim 1, wherein the bank layer includes:
a first bank layer; and
a second bank layer on the first bank layer, the second bank layer including at least one bank opening.

9. The display apparatus of claim 8, wherein the bank opening is formed at two sides of the first pattern and/or two sides of the second bank layer.

10. The display apparatus of claim 9, wherein the auxiliary electrode is formed inside of the bank opening and the second electrode is formed on the auxiliary electrode within the bank opening.

11. The display apparatus of claim 1, further comprising a low potential voltage line on the bank layer.

12. The display apparatus of claim 11, wherein the first pattern is disposed on the bank layer and a first pattern opening is formed in the first pattern so that the low potential voltage line is exposed through the first pattern opening.

13. The display apparatus of claim 12, wherein the second pattern is formed in the first pattern opening.

14. The display apparatus of claim 13, wherein the auxiliary electrode is formed on side and upper surfaces of the first pattern opening and inside the first pattern opening so that the auxiliary electrode is connected electrically to the low potential voltage line in the first pattern opening.

15. The display apparatus of claim 14, wherein the second electrode is connected to the auxiliary electrode on the side surface of the first pattern.

16. The display apparatus of claim 1, further comprising:
a second encapsulation layer formed on the entire area of the substrate and on the plurality of first encapsulation layers; and
a third encapsulation layer on the second encapsulation layer.

17. The display apparatus of claim 1, wherein the light emitting layer includes an organic light emitting layer, an inorganic light emitting layer, a nano-sized material layer, a quantum dot layer, a micro LED light emitting layer, or a mini LED light emitting layer.
